(19) United States
(12) Patent Application Publication
(10) Pub. No.: US 2010/0045292 A1
(43) Pub. Date: Feb. 25, 2010

(54) MAGNETIC RESONANCE ANGIOGRAPHY METHOD AND APPARATUS

(76) Inventor: Michael Zenge, Nuernberg (DE)

Correspondence Address: SCHIFF HARDIN, LLP;PATENT DEPARTMENT, 233 S. Wacker Drive-Suite 6600, CHICAGO, IL, 60606-6473, US

(21) Appl. No.: 12/545,917

(22) Filed: Aug. 24, 2009

(30) Foreign Application Priority Data
Aug. 25, 2008 (DE) 10 2008 039 581.1

(51) Int. Cl. G01R 33/44

(52) U.S. Cl. 324/309

(57) ABSTRACT

In a magnetic resonance apparatus and method for generation of a magnetic resonance angiogram of a subphrenic vessel structure, a subject containing the subphrenic vessel structure is positioned in an imaging volume of a magnetic resonance apparatus, and MR measurement data are acquired using a radial k-space scanning scheme. An image of the vessel structure is reconstructed from the measurement data. Information about movement of the vessel structure to be examined is determined from the acquired measurement data and a movement correction is implemented in the reconstruction of the image using the extracted information.

### BACKGROUND OF THE INVENTION

1. Field of the Invention

The invention concerns a method to generate a magnetic resonance angiogram of a subphrenic vascular structure and a magnetic resonance apparatus to implement such a method. The invention in particular concerns use in the generation of angiograms to assess a renal artery.

2. Description of the Prior Art

Magnetic resonance technology (in the following the term “magnetic resonance” is also shortened to MR) is thereby a technique that has been known for several decades with which images of the inside of an examination subject can be generated. Described in a significantly simplified way, for this the examination subject is positioned in a relatively strong, static, homogeneous basic magnetic field (field strengths of 0.2 Tesla to 7 Tesla or more) so that nuclear spins in the subject orient along the basic magnetic field. Radio-frequency excitation pulses are radiated into the examination subject to excite nuclear magnetic resonances, the resonant nuclear spin signal is measured and MR images are reconstructed based thereon. For spatial coding of the measurement data, rapidly switched gradient fields are superimposed on the basic magnetic field. The acquired measurement data are digitized and stored as complex numerical values in a k-space matrix. By means of a multidimensional Fourier transformation, an associated MR image can be reconstructed from the k-space matrix populated with such values.

The magnetic resonance technique can also be used to generate a non-invasive angiogram. Magnetic resonance techniques are thereby known with which an angiogram can be generated without the use of a contrast agent, for example phase contrast angiography or time-of-flight angiography. In addition to this it is also possible to use a contrast agent to increase the contrast.

Magnetic resonance angiography is also used for (among other things) presentation of renal vessels. Pathologically altered renal vessels, for example due to a renal artery stenosis, represent an important cause of secondary hypertension. Such illnesses often occur in older patients with multiple cardiovascular risk factors additionally worsen the (often already strained) health status.

Contrast agent-assisted magnetic resonance angiograms deliver a very good quality for the presentation of the renal arteries, however have the disadvantage that the contrast agent that is used can cause kidney damage, for example a systemic kidney fibrosis.

In the document Katoh M et al., “Free-breathing renal MR angiography with steady-state free-precession (SSFP) and slab-selective spin inversion: Initial results”, Kidney International, 66(3), 2004, pp. 1272-1278, a contrast agent-free sequence for acquisition of an angiogram is disclosed. Since the acquisition of the measurement data ensues during free breathing, a navigator technique is used in order to determine that time window (“gating window”) during which the acquisition of the measurement data can ensue. In this way artifacts that would be caused by the breathing movement are largely prevented. Such methods are also known, called “gating” methods.

In the document by Stehning C et al., “Free-breathing whole-heart coronary MRA with 3D radial SSFP and self-navigated image reconstruction”, Magnetic resonance in medicine, 54(2), 2005, pp. 476-480, a radial k-space scanning scheme is disclosed, which is used for imaging the heart and which allows a movement occurring during the acquisition to be determined and taken into account in the reconstruction.

### SUMMARY OF THE INVENTION

It is the object of the invention to provide a method for magnetic resonance angiography that allows a fast and qualitatively high-grade imaging of subphrenic vessels even given a movement of the subphrenic vessels. Furthermore, it is an object of the invention to specify a magnetic resonance apparatus to implement such a method.

The method according to the invention for the generation of a magnetic resonance angiogram of a subphrenic vessel structure includes the following steps.

A subject containing the subphrenic vessel structure in question is positioned in an imaging volume of a magnetic resonance apparatus. MR measurement data are acquired from the subject (vessel structure) using a radial k-space scanning scheme. An image is reconstructed from the measurement data. Information about a movement of the vessel structure in question is determined from the acquired measurement data, and a movement correction is implemented using the determined information in the reconstruction of the image.

The invention is based on the insight that radial k-space scanning is particularly insensitive to a movement of the vessel structure to be examined, and therefore is advantageously suitable for the acquisition of the MR measurement data in this situation. In particular, the radial scanning scheme allows an acquisition of the measurement data to be conducted during free breathing, in particular without using a “gating” method. It is thus possible to significantly accelerate the acquisition of the measurement data that are necessary for an image reconstruction. Compared with known methods, up to a 100% more efficient utilization of the available acquisition time can be achieved, which overall allows a shorter examination time and/or can be used for a higher spatial resolution of the acquired images.

The implementation of the movement correction means that the information that was determined from the acquired measurement data and that characterize the movement—i.e. the position and/or the position change—of the vessel structure to be examined is calculated with the acquired measurement data. Artifacts that are to be ascribed to a movement of the vessel structure to be examined are eliminated at least in part (if not almost entirely) in this way in a subsequent image reconstruction.

The radial k-space scanning scheme is preferably a three-dimensional radial k-space scanning scheme. In such a scanning scheme, the measurement data are not scanned along a Cartesian coordinate system, but rather along various directions in k-space, with the directions being rotated relative to one another around a k-space center. The k-space lines thus proceed in k-space such that they pass through the center of k-space.

The acquisition of the measurement data advantageously occurs with free breathing. This can now be implemented in a simple manner due to the use of the radial k-space scanning scheme without, for example, having to determine time windows encompassing an advantageous movement profile of the structure to be examined.

In an embodiment, the acquisition of the measurement data is triggered via an EKG signal. An inversion pulse can be applied before acquisition of the image-relevant measurement data, i.e. the measurement data in which the information relevant to the reconstruction of the image is contained. Nuclear spins of tissue structures that are of subordinate importance for the angiography diagnosis can be prepared with such an inversion pulse so that they generate no or only a small signal in the subsequent acquisition of the measurement data. A good vessel contrast can be achieved in this way.

In one advantageous embodiment, the acquisition of the measurement data includes the acquisition of a navigator signal. This signal allows the information about the movement of the vessel structure to be examined to be determined, which movement has occurred in the acquisition of the measurement data acquired with the navigator signal.

Such a navigator signal is helpful in the determination of the current movement state in the acquisition of the respective group of the measurement data, in particular when the measurement data are scanned in groups (for example are divided into different cardiac cycles).

For example, the navigator signal can be a k-space line that is scanned in every acquisition of a group of measurement data. In this way the navigator signals are directly comparable with one another. The radial projection along this k-space line (which can be determined from the navigator signal) allows a direct detection of the movement. Such a navigator signal thus allows the information about the movement of the vessel structure to be directly determined from the navigator signal. A rigid movement of the vessel structure to be examined (“rigid body motion”) thus can be detected along the direction of the k-space line of the navigator signal.

A contrast agent-free steady state free precession sequence can be used to acquire the measurement data. A renal artery is shown as a subphrenic vessel structure.

The magnetic resonance apparatus according to the invention has a control device configured (programmed) to implement the method described above.

### BRIEF DESCRIPTION OF THE DRAWINGS

FIG. 1 schematically illustrates the basic design of a magnetic resonance apparatus.

FIG. 2 shows a three-dimensional radial k-space scanning scheme used in accordance with the invention.

FIG. 3 schematically illustrates the time sequence of the acquisition of the measurement data relative to the cardiac cycle in accordance with the invention.

### DESCRIPTION OF THE PREFERRED EMBODIMENTS

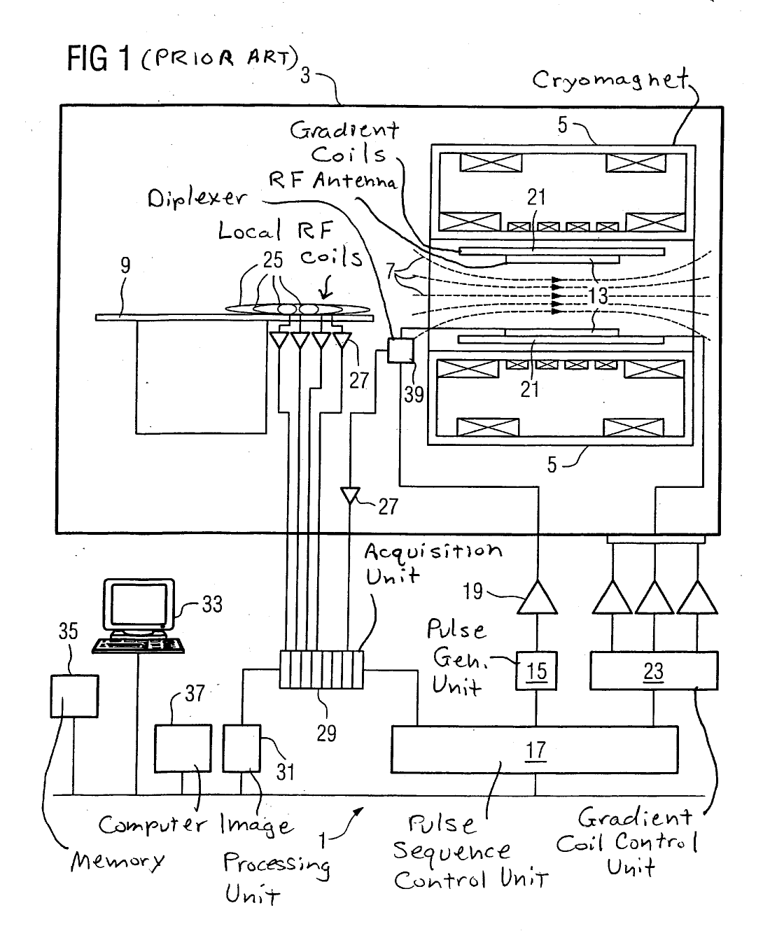

FIG. 1 schematically shows the design of a magnetic resonance apparatus 1 with its basic components. In order to examine a body by means of magnetic resonance imaging, different magnetic fields tuned to one another as precisely as possible in terms of their temporal and spatial characteristics are radiated at the body.

A strong magnet (typically a cryomagnet 5 with a tunnel-shaped opening) arranged in a measurement chamber shielded against radio frequencies generates a strong, static basic magnetic field 7 that is typically 0.2 Tesla to 3 Tesla or more. A body or a body part 41 (not shown here) to be examined is placed on a patient bed 9 and is subsequently positioned in a homogeneous region of the basic magnetic field 7 (not shown).

The excitation of the nuclear spins of the body ensues via magnetic radio-frequency excitation pulses that are radiated via a radio-frequency antenna (shown here as a body coil 13). The radio-frequency excitation pulses are generated by a pulse generation unit 15 that is controlled by a pulse sequence control unit 17. After an amplification by a radio-frequency amplifier 19, they are conducted to the radio-frequency antenna. The radio-frequency system shown here is only schematically indicated. Typically, more than one pulse generation unit 15, more than one radio-frequency amplifier 19 and multiple radio-frequency antennas are used in a magnetic resonance apparatus 1.

Furthermore, the magnetic resonance apparatus 1 has gradient coils 21 with which magnetic gradient fields for selective slice excitation and for spatial coding of the measurement signal are radiated in a measurement. The gradient coils 21 are controlled by a gradient coil control unit 23 that, like the pulse generation unit 15, is connected with the pulse sequence control unit 17.

The signals emitted by the excited nuclear spins are received by the body coil 13 and/or by local coils 25, amplified by associated radio-frequency preamplifiers 27 and further processed and digitized by an acquisition unit 29.

If a coil is used that can be operated both in transmission and in reception mode, for example the body coil 13, the correct signal relaying is regulated via an upstream transmission/reception diplexer 39.

From the measurement data, an image processing unit 31 generates an image that is presented to a user via an operator console 33 or is stored in a memory unit 35. A central computer 37 controls the individual system components.

Such an MR apparatus corresponds to an MR apparatus as is known in the prior art.

The computer 37 (and, if necessary, additional components for controlling the MR apparatus) are configured to implement the method according to the invention with the MR apparatus, as is subsequently explained in detail.

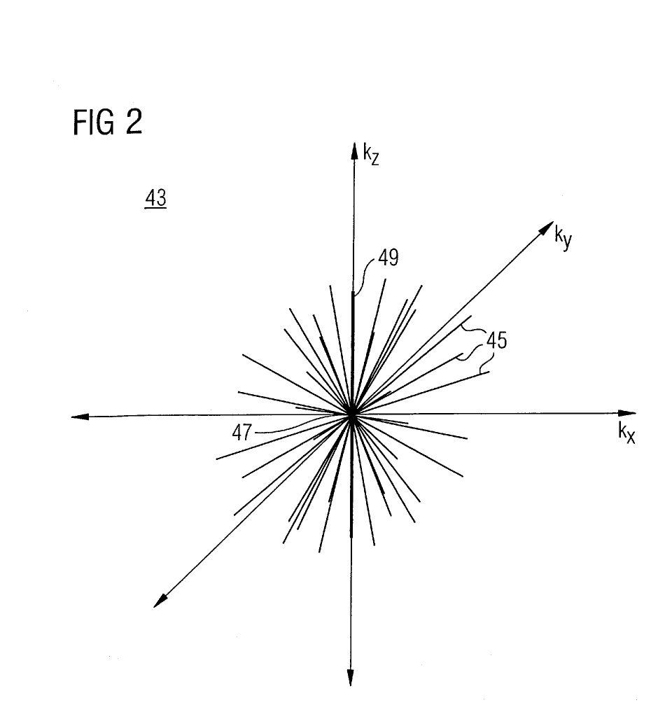

FIG. 2 shows a radial, three-dimensional k-space scanning scheme. The scanning of k-space 43 ensues along a number of linearly aligned k-space lines 45. The k-space lines 45 are thereby rotated relative to one another around a k-space center 47. For readout of the k-space lines 45, the gradient fields necessary for scanning are correspondingly switched so that the desired spatial orientation of the k-space lines 45, or of the readout direction, results along these k-space lines 45.

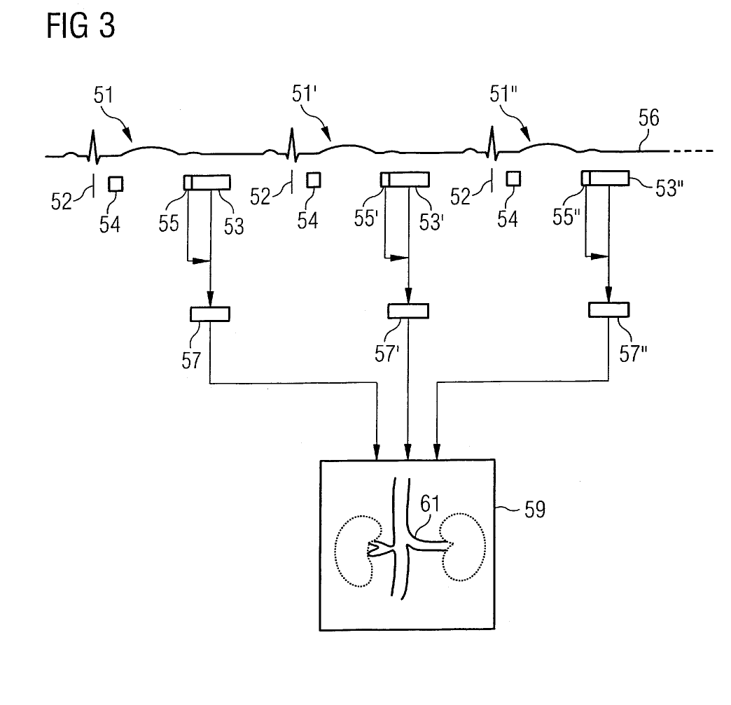

One of the k-space line 45 is oriented along the z-direction of k-space kz and represents an assigned k-space line 49 that serves for marking of navigator signals as it is described in the following using FIG. 3.

It is typically not possible to scan all k-space lines 45 within one cardiac cycle 51, 51′, 51″, . . . since the scanning of the entirety of the k-space lines 45 would take too long. Therefore the k-space lines 45 are grouped and scanned distributed across multiple cardiac cycles 51, 51′, 51″.

For this purpose, trigger points in time 52 with which the acquisition of the measurement data is triggered are determined from an EKG signal. The application of an inversion pulse 54 initially follows a trigger point in time 52 in order to largely suppress signals from structures that are of subordinate importance for an angiography in the following measurement data acquisition.

The acquisition of the actual measurement data 53, 53′, 53″ . . . ensues at a time interval relative to the inversion pulse. The acquisition of the navigator signal 55, 55′, 55″ . . . respectively ensues at the beginning of this acquisition in that the marked k-space line 49 of k-space 43 is always scanned. In the following acquisition of the measurement data 53, 53′, 53″ . . . with the image-relevant information, respective other groups of k-space lines are scanned in every cardiac cycle until all k-space lines have been scanned.

Information describing what the movement state of the vessel structure to be examined was at the point in time of the acquisition of the respective subsequent group of k-space lines can be obtained from the navigator signal 55, 55′, 55″ . . . , i.e. from the measurement data of this marked k-space line 49.

The measurement data 53, 53′, 53″ . . . of the k-space lines of a group can correspondingly be corrected with the aid of the movement information which can be obtained from the associated navigator signal 55, 55′, 55″ . . . .

A significant elimination of movement artifacts that would be present without correction of the measurement data can hereby be achieved in an image 59 that is reconstructed from the movement-corrected measurement data 57, 57′, 57″ . . . . A correction of the measurement data can ensue with the methods described in the document by Stehning et al., for example.

K-space 43 is oriented such that the z-direction kz of k-space 43 substantially coincides with the expected movement direction of the vessel structure to be examined.

This is particularly advantageous when information about a rigid body motion of the vessel structure is determined from the one-dimensional navigator signal 55, 55′, 55″ . . . . Namely, only information about a movement along the direction of the k-space line 49 can be determined from the one-dimensional navigator signal 55, 55′, 55″ . . . . A movement perpendicular to the direction of this k-space line 49 is not detected by the navigator signal 55, 55′, 55′ . . . .

The entire acquisition of the measurement data thereby ensues during free breathing of the patient. Furthermore, no “gating” is used, meaning that no time windows for measurement data acquisition which correlate with a breathing movement of the lungs are determined in the acquisition of the measurement data. A steady state free precession sequence can be used as a sequence.

The method can in particular be used for presentation of a renal artery 61, for example for diagnosis of a renal artery stenosis.

Although modifications and changes may be suggested by those skilled in the art, it is the intention of the inventor to embody within the patent warranted hereon all changes and modifications as reasonably and properly come within the scope of his contribution to the art.

I claim as my invention:

1. A method for generating a magnetic resonance angiogram of a subphrenic vessel structure, comprising the steps of:
positioning a subphrenic vessel structure in an examination subject in an imaging volume of a magnetic resonance data acquisition apparatus;
operating said magnetic resonance data acquisition apparatus to acquire magnetic resonance measurement data, representing the subphrenic vessel structure, using a radial k-space scanning scheme;
in a processor, automatically determining information identifying movement of said subphrenic vessel structure from the acquired magnetic resonance measurement data; and
in a computer, reconstructing an image of the subphrenic vessel structure from the magnetic resonance measurement data and automatically implementing a motion correction, using said information, while reconstructing said image.

2. A method as claimed in claim 1 comprising acquiring said magnetic resonance measurement data using a three-dimensional radial k-space scanning scheme.

3. A method as claimed in claim 1 comprising acquiring said magnetic resonance measurement data during free breathing of said subject.

4. A method as claimed in claim 1 comprising obtaining an EKG signal from the subject, and triggering acquisition of said magnetic resonance measurement data dependent on said EKG signal.

5. A method as claimed in claim 1 wherein said magnetic resonance measurement data comprise image-relevant measurement data, and applying inversion pulse in said magnetic resonance data acquisition apparatus before acquiring said image-relevant measurement data.

6. A method as claimed in claim 1 comprising acquiring a navigator signal in said magnetic resonance measurement data, and determining said information about movement of said subphrenic vessel structure using said navigator signal.

7. A method as claimed in claim 6 comprising generating said navigator signal by scanning a k-space line, and determining said information about movement of said subphrenic vessel structure as information describing a rigid movement of said subphrenic vessel structure along a direction of said k-space line.

8. A method as claimed in claim 1 comprising acquiring said magnetic resonance measurement data using a steady state free precession magnetic resonance data acquisition sequence, without administration of a contrast agent to the subject.

9. A method as claimed in claim 1 comprising acquiring magnetic resonance measurement data representing a renal artery as said subphrenic vessel structure.

10. A magnetic resonance apparatus comprising:
a magnetic resonance data acquisition unit configured to receive a subject therein containing a subphrenic vessel structure, with the subphrenic structure positioned within an imaging volume of the magnetic resonance data acquisition unit;
a control unit configured to operate the magnetic resonance data acquisition unit to acquire magnetic resonance data representing said subphrenic vessel structure, using a radial k-space scanning scheme;
a processor configured to automatically determine information indicating a movement of said subphrenic vessel structure from the acquired magnetic resonance measurement data; and
an image reconstruction computer configured to reconstruct an image of the subphrenic vessel structure, and implementing a motion correction, dependent on said information, while reconstructing said image.
